(19) United States
(12) Patent Application Publication
(10) Pub. No.: US 2010/0078728 A1
(43) Pub. Date: Apr. 1, 2010

(54) RAISE S/D FOR GATE-LAST ILD0 GAP FILLING

(75) Inventors: Hou-Ju Li, Hsinchu (TW); Chung Long Cheng, Baoshan Township (TW); Kong-Beng Thei, Hsin-Chu Country (TW); Harry Chuang, Hsin-Chu City (TW)

Correspondence Address: David M. O'Dell;Haynes and Boone, LLP, Suite 3100, 901 Main Street, Dallas, TX, 75202-3789, US

(73) Assignee: TAIWAN SEMICONDUCTOR MANUFACTURING COMPANY, LTD., Hsin-Chu (TW)

(21) Appl. No.: 12/546,475

(22) Filed: Aug. 24, 2009

Related U.S. Application Data
(60) Provisional application No. 61/092,597, filed on Aug. 28, 2008.

(51) Int. Cl. H01L 27/092; H01L 29/78; H01L 21/8238

(52) U.S. Cl. 257/369; 257/288; 438/230; 257/E29.255; 257/E27.062; 257/E21.634

(57) ABSTRACT

The present disclosure provides an integrated circuit having metal gate stacks. The integrated circuit includes a semiconductor substrate; a gate stack disposed on the semiconductor substrate, wherein the gate stack includes a high k dielectric layer and a first metal layer disposed on the high k dielectric layer; and a raised source/drain region configured on a side of the gate stack and formed by an epitaxy process, wherein the semiconductor substrate includes a silicon germanium (SiGe) feature underlying the raised source/drain region.

### PRIORITY DATA

This application claims priority to Provisional Application Ser. No. 61/092,597 filed on Aug. 28, 2008, entitled “Raised S/D For Gate-Last ILD0 Gap Filling”, the entire disclosure of which is incorporated herein by reference.

### BACKGROUND

When a semiconductor device such as a metal-oxide-semiconductor field-effect transistors (MOSFETs) is scaled down through various technology nodes, high k dielectric material and metal are adopted to form a gate stack. In a method to form such a device, an inter-level dielectric (ILD) layer will be formed on the substrate and filled in the regions between adjacent gates. However, when an array of gates becomes more dense and has a smaller pitch, the ILD layer cannot be effectively filled in the areas between the adjacent gate regions. Voids may be formed in the ILD layer and further cause metal residue or open contact. Therefore, a structure and a method to make the same are needed to address the various issues associated with ILD voids.

### SUMMARY

One of the broader forms of an embodiment of the present invention involves an integrated circuit having metal gate stacks. The integrated circuit includes a semiconductor substrate; a gate stack disposed on the semiconductor substrate, wherein the gate stack includes a high k dielectric layer and a first metal layer disposed on the high k dielectric layer; and a raised source/drain region configured on a side of the gate stack and formed by an epitaxy process. The semiconductor substrate includes a silicon germanium (SiGe) feature underlying the raised source/drain region.

Another one of the broader forms of an embodiment of the present invention involves an integrated circuit having metal gate stacks. The integrated circuit includes a semiconductor substrate; an N metal-oxide-semiconductor (NMOS) transistor formed on the semiconductor substrate; and a PMOS transistor formed on the semiconductor substrate. The NMOS transistor includes a first gate stack having a high k dielectric layer and a first metal layer on the high k dielectric layer; a first gate spacer disposed on sidewalls of the first gate stack; and a first raised source and a first raised drain laterally contacting sidewalls of the first gate spacer. The PMOS transistor includes a second gate stack having the high k dielectric layer and a second metal layer on the high k dielectric layer; a second gate spacer disposed on sidewalls of the second gate stack; and a second raised source and a second raised drain laterally contacting sidewalls of the second gate spacer.

Yet another one of the broader forms of an embodiment of the present invention involves a method of making an integrated circuit having metal gate stacks. The method includes forming a dummy gate stack on a semiconductor substrate; forming epitaxy silicon germanium (SiGe) source and drain in the semiconductor substrate, aligned with the gate stack; forming a gate spacer on sidewalls of the gate stack; and thereafter, applying an epitaxy process to form a raised source and a raised drain, aligned with the gate spacer and laterally contacting sidewalls of the gate spacer.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. Various drawings and associated text are provided in a Power Point file. Particularly,

FIG. 1 is a sectional view of a semiconductor structure having a metal gate stack.

FIG. 2 is a sectional view of a semiconductor structure having a metal gate stack constructed according to aspects of the present disclosure.

FIGS. 3 through 6 are sectional views of a semiconductor structure having a metal gate stack at various fabrication stages constructed according to various aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

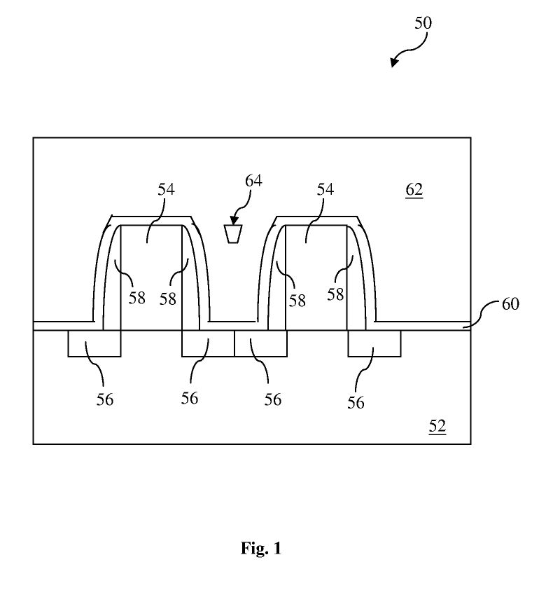

FIG. 1 is a sectional view of a semiconductor structure 50 constructed according to aspects of the present disclosure. The semiconductor device 50 includes a semiconductor substrate 52 and one or more gate stacks 54 formed thereon. The semiconductor device 50 also includes a source and a drain 56 formed in the substrate and disposed on two sides of each gate stack. Each gate stack includes a high k dielectric material layer and a conductive layer formed on the high k dielectric layer, and further includes a hard mask layer disposed on the conductive layer. The semiconductor device further includes a gate spacer 58 disposed on the sidewalls of the gate stack. An etch stop layer (ESL) 60 is additionally formed on top of the associated gate stack and sidewalls of the spacer. An inter-level dielectric (ILD or specifically referred to as ILD0) layer 62 is formed on the top of the gate stacks and in the gaps between the adjacent gate stacks. As the gap between the adjacent gate stacks is small when the device is scaled down to small dimensions, the ILD layer may not be properly filled in the gap and leaves a void 64 there and may cause metal residue and contact open. In one example, the conductive layer includes polysilicon. In another example, the conductive layer includes a metal layer and a polysilicon layer on the metal layer.

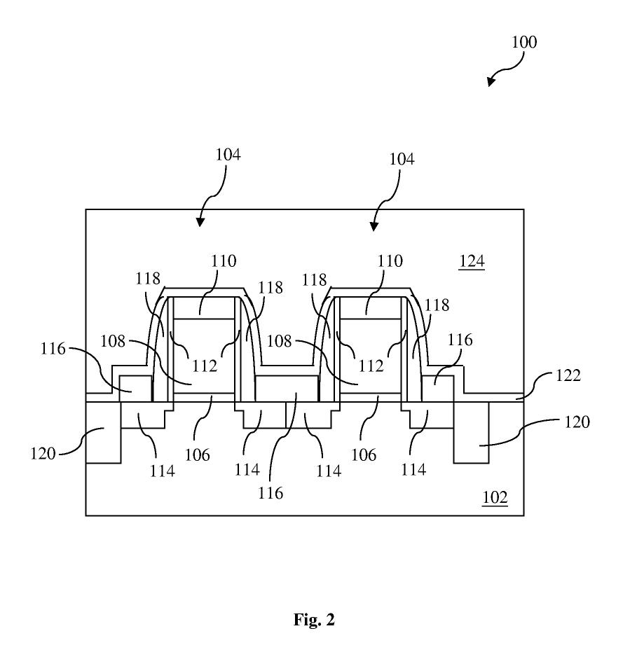

FIG. 2 is a sectional view of a semiconductor structure 100 having a metal gate stack constructed according to aspects of the present disclosure. The semiconductor device 100 includes a semiconductor substrate 102 and one or more gate stacks 104 formed thereon. Each gate stack includes a high k dielectric material layer 106 and a conductive layer 108 formed on the high k dielectric layer, and further includes a hard mask layer 110 disposed on the conductive layer. The semiconductor device 100 further includes a gate spacer 112 disposed on the sidewalls of the gate stack. In one example, the conductive layer includes polysilicon. In another example, the conductive layer includes a metal layer and a polysilicon layer on the metal layer.

The semiconductor device 100 also includes a first source and a first drain, collectively referred to as 114, formed in the substrate and disposed on two sides of each gate stack. Additionally, raised source and raised drain features 116 are formed on the semiconductor substrate, laterally contacting the sidewalls of the gate spacer and vertically contacting the first source and first drain, respectively, as illustrated in FIG. 2. The raised source and drain features 116 are formed by an epitaxy process after the formation of the gate spacer. In one embodiment, the raised source and drain features have silicon and formed by a silicon epitaxy process such that silicon is formed in crystalline form on the first source and first drain. In one example, the raised source and drain has a thickness of about 200 angstrom. In another example, the raised source and drain has a thickness ranging between about 100 angstrom and about 400 angstrom. As the raised source and drain features are formed after the formation of the gate spacer and therefore fill in the lower portion of the gap between the adjacent gate spacers, as illustrated in FIG. 2.

In one embodiment, the first source and drain includes light doped drain (LDD) and heavily doped S/D. In another embodiment, the spacer on the sidewalls of the gate stacks include the first spacer 112 and further include a second spacer 118 in a way such that LDD is aligned with the outer edges of sidewalls of the gate stacks, the heavily doped S/D are aligned with the edges of the first spacer 112 and the raised source and drain are aligned with the edge of the second spacer 112. In one procedure, the LDD is formed after the gate stacks, then the first spacer 112 is formed, the heavily doped S/D are formed thereafter, the second spacer 118 is formed, and thereafter the raised S/D are formed. In another embodiment, the semiconductor substrate 102 further includes various isolation features, such as shallow trench isolation (STI) 120.

An etch stop layer (ESL) 122 is additionally formed on top of the associated gate stack and on the raised source/drain located in the gap between the adjacent gate stacks. An ILD layer 124 is formed on the top of the gate stacks and in the gaps between the adjacent gate stacks. As the lower portion of the gap is filled by the raised source and drain 116, the narrow portion of the gap is eliminated when the ILD layer is filled in the gap. Therefore, the ILD layer 124 in the gap between the adjacent gate stacks is substantially void free and the device integrity is improved.

In various examples for illustration, the ESL has a thickness ranging between about 200 angstrom and 400 angstrom. The gate stack has a thickness ranging between about 600 angstrom and 1200 angstrom. In one embodiment, the gate stack further includes a polysilicon layer interposed between the metal layer and the hard mask layer. The gate stack also includes an interfacial layer interposed between the high k dielectric layer and the semiconductor substrate. In one embodiment, various material layer of the gate stack are sequentially formed and then patterned by a process including lithography exposure and an etching process. Then LDD features are formed in the substrate. Then the gate spacer is formed on the sidewalls of the gate stack and then first source and drain are formed in the substrate. The raised source and drain features are formed thereafter.

Various subsequent processing steps may follow to form the device 100. In one embodiment, a chemical mechanical polishing (CMP) process is applied to the ILD to polish until the gate stack is exposed or partially removed. In the disclosed method and above device structure 100, the gate stack can be used as a dummy gate such that one or more portions of the gate stack are removed, resulting gate trench defined by the gate spacer. Then one or more metal material layers are filled in the gate trench to form the metal gate stack of the semiconductor device. This processing flow is also referred to as gate last process since the metal gate is formed after the formation of source and drain. In one embodiment, the polysilicon layer is removed and then a metal layer is filled into the associated gate trench for NMOS transistor and PMOS transistor separately. In another embodiment, the first source and drain in the PMOS transistor include silicon germanium (SiGe) features formed by an epitaxy process such that a SiGe features can be formed in crystalline state in a silicon substrate. Thereby, the strained channel can be achieve in the PMOS transistor to increase the carrier mobility and enhance the device performance.

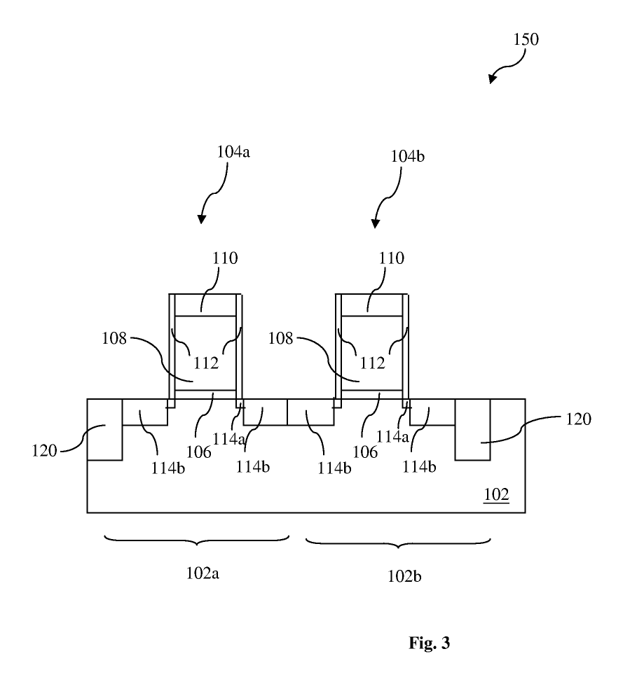

FIGS. 3 through 6 are sectional views of another embodiments of a semiconductor structure having a metal gate stack at various fabrication stages constructed according to various aspects of the present disclosure. With reference to FIGS. 3 through 6, a semiconductor device 150 and a method of making the same are collectively described below.

Referring to FIG. 3, the semiconductor device 150 includes a semiconductor substrate having a NMOS transistor region 102a and a PMOS transistor region 102b. An NMOS gate stack 104a and a PMOS gate stack 104b are formed on the semiconductor substrate within the NMOS transistor region 102a and PMOS transistor region 102b, respectively. Each gate stack includes a high k dielectric material layer 106 and a polysilicon layer 108 formed on the high k dielectric layer, and further includes a hard mask layer 110 disposed on the polysilicon layer. In one example, each gate stack further includes capping layer formed between the polysilicon layer 108 and the high k dielectric layer 106. In another example, an interfacial layer, such as silicon oxide, is formed between the semiconductor substrate 102 and the high k dielectric layer 106. In one embodiment, the semiconductor substrate 102 further includes isolation features, such as shallow trench isolation 120.

The semiconductor device 150 further includes LDD regions 114a formed on the substrate by one or more ion implantation processes and aligned with the associated gate stack, separately for the NMOS transistor and PMOS transistor. The semiconductor device 150 further includes gate spacers disposed on sidewalls of each gate stack. The first gate spacers 112 are formed on sidewalls of the gate stacks in one embodiment. Then heavily doped source and drain (or source and drain or S/D) 114b are formed in the substrate by one or more ion implantation processes and aligned with the first gate spacers 112, for the NNMOS transistor and PMOS transistor separately.

Additionally, silicon germanium (SiGe) features are formed on the PMOS transistor region of the substrate by an epitaxy process such that a SiGe features can be formed in crystalline state on the silicon substrate. Thereby, the strained channel can be achieved in the PMOS transistor to increase the carrier mobility and enhance the device performance. The formation of the SiGe features can be implemented before the formation of the source and drain. Thus the source and drain ion implantation process is applied to the SiGe features in the PMOS transistor region. The NMOS transistor region is protected by a patterned mask layer while forming the SiGe features. In one example, the patterned mask layer is a patterned photoresist formed by a lithography process. In one embodiment, the epitaxy process is directly applied to the silicon substrate within the PMOS transistor region. In another embodiment, the source and drain regions in the PMOS transistor region are recessed by an etching process and then a SiGe epitaxy process is applied to the recessed source and drain region in the PMOS transistor. In this case, the source and drain include SiGe.

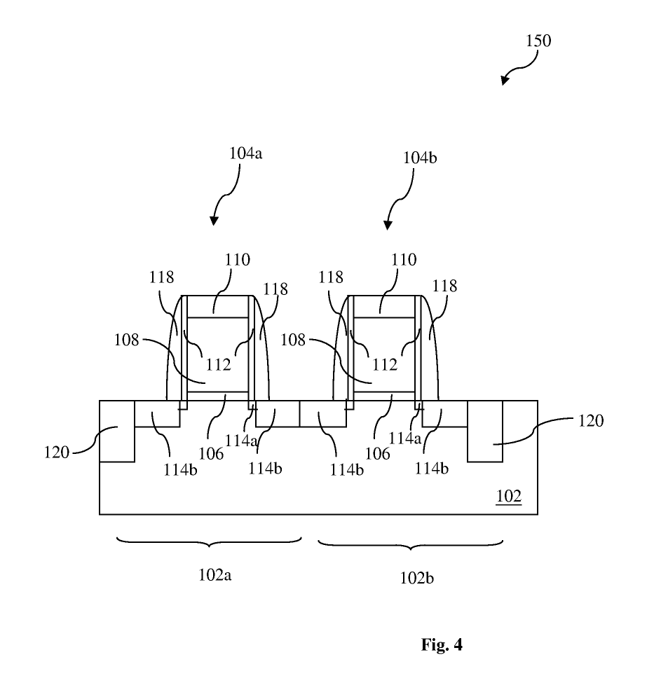

Referring to FIG. 4, second gate spacers 118 are formed on sides of the gate stacks. In one embodiment, the second gate spacers are formed on sidewalls of the first gate spacers 112 and laterally contact the first gate spacers.

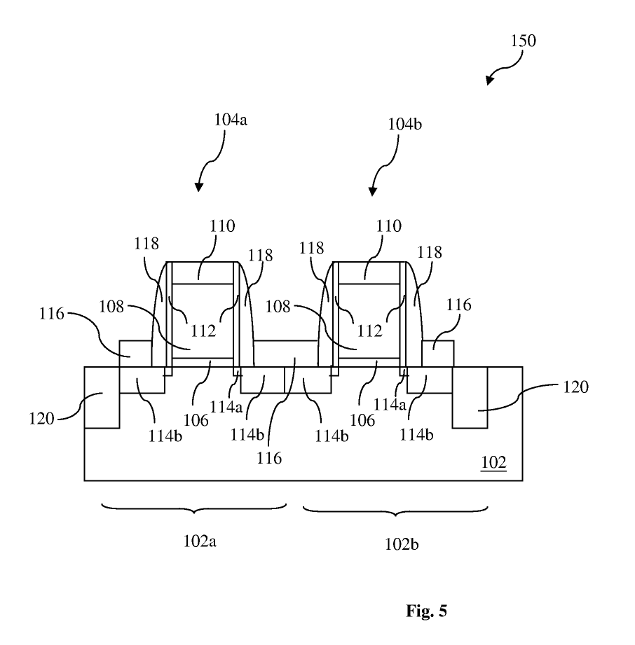

Referring to FIG. 5, raised source and raised drain features (or raised source and drain) 116 are formed on the semiconductor substrate 102, laterally contacting the sidewalls of the second gate spacers 118 and vertically contacting the source and drain 114b formed in FIG. 3. The raised source and drain 116 are formed by an epitaxy process after the formation of the gate spacer. In one embodiment, the raised source and drain 116 have silicon and formed by a silicon epitaxy process such that silicon is formed in crystalline form on the first source and first drain. In one example, the raised source and drain 116 has a thickness of about 200 angstrom. In another example, the raised source and drain 116 has a thickness ranging between about 100 angstrom and about 400 angstrom. The raised source and drain are formed after the formation of the gate spacer and therefore fill in the lower portion of the gap between the adjacent gate spacers, as illustrated in FIG. 5.

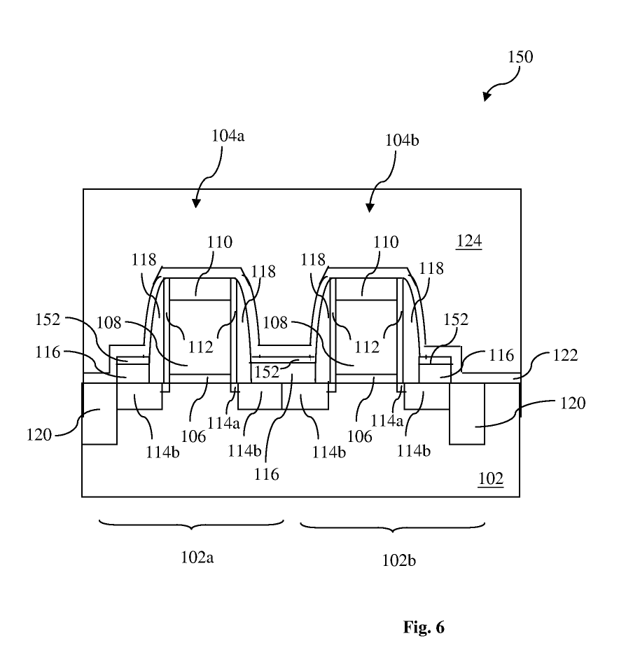

Referring to FIG. 6, a silicide layer (or silicide) 152 is formed on the raised source and drain features to reduce the contact resistance. The silicide 152 can be formed by a process including depositing a metal layer, annealing the metal layer such that the metal layer is able to react with silicon to form the silicide, and then removing the non-reacted metal layer.

Other processes may present to from a semiconductor device with metal gates. In one example, an etch stop layer (ESL) 122 is formed on top of the gate stacks and on the raised source/drain located in the gaps between the adjacent gate stacks. An ILD layer 124 is formed on the ESL layer, filling in the gaps between the adjacent gate stacks. As the lower portion of the gap is filled by the raised source and drain, the narrow portion of the gap is eliminated in the filled ILD layer. Therefore, the ILD layer 124 in the gap between the adjacent gate stacks is substantially void free. In various examples for illustration, the ESL layer 122 has a thickness ranging between about 200 angstrom and 400 angstrom. The gate stack, such as 104a or 104b, has a thickness ranging between about 600 angstrom and 1200 angstrom. In one embodiment, the gate stack also includes an interfacial layer, such as silicon oxide, interposed between the high k dielectric layer 106 and the semiconductor substrate 102.

Other processing steps may follow. In one embodiment, a chemical mechanical polishing (CMP) process is applied to the ILD to polish thereof until the gate stack is exposed or partially removed. In one embodiment of the disclosed method and semiconductor device 150, the gate stacks are used as a dummy gate such that one or more portions of the gate stack are removed thereafter, resulting gate trenches defined by the gate spacer. One or more metal material layers are then filled in the gate trenches to form the metal gate stacks of the semiconductor device. In one embodiment, the polysilicon layer is removed and then a metal layer (or metal gate layer) is filled into the associated gate trench for the NMOS transistor and PMOS transistor separately. In this case, the metal layer of the NMOS is different from the metal layer of the PMOS for proper work function tuning. The metal layer may include TiN, TaN, WN, TiAl, TiAlN or Ti in various combinations tuned for NMOS and PMOS transistors separately.

In one embodiment, the high k dielectric material layer is formed by a suitable process such as an atomic layer deposition (ALD). Other methods to form the high k dielectric material layer include metal organic chemical vapor deposition (MOCVD), physical vapor deposition (PVD), UV-Ozone Oxidation and molecular beam epitaxy (MBE). In one embodiment, the high k dielectric material includes HfO2. In another embodiment, the high k dielectric material includes Al2O3. Alternatively, the high k dielectric material layer includes metal nitrides, metal silicates or other metal oxides.

The metal gate layer is formed by PVD or other suitable process. The metal gate layer includes titanium nitride. The capping layer may be further interposed between the high k dielectric material layer and the metal gate layer. The capping layer includes lanthanum oxide (LaO) or other suitable material. A second metal layer can be disposed on the first metal layer and substantially filled in the gate trench formed between. The second metal layer may include aluminum or tungsten.

In one example, the gate spacers may have a multilayer structure and may include silicon oxide, silicon nitride, silicon oxynitride, or other dielectric material. N-type dopant impurities employed to form the associated doped regions may include phosphorus, arsenic, and/or other materials. P-type dopant impurities may include boron, indium, and/or other materials.

A multilayer interconnection (MLI) structure is further formed. The multilayer interconnection includes vertical interconnects, such as conventional vias or contacts, and horizontal interconnects, such as metal lines. The various interconnection features may implement various conductive materials including copper, tungsten and silicide. In one example, a damascene process is used to form copper related multilayer interconnection structure. In another embodiment, tungsten is used to form tungsten plug in the contact holes.

The semiconductor substrate includes silicon. Alternatively, the substrate may includes germanium or silicon germanium. The semiconductor substrate may further include additional isolation features to isolate each from other devices. The isolation features may include different structures and can be formed using different processing technologies. For example, an isolation feature may include shallow trench isolation (STI) features. The formation of STI may include etching a trench in a substrate and filling the trench by insulator materials such as silicon oxide, silicon nitride, or silicon oxynitride. The filled trench may have a multi-layer structure such as a thermal oxide liner layer with silicon nitride filling the trench. In one embodiment, the STI structure may be created using a process sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical planarization (CMP) to etch back, and using nitride stripping to leave the STI structure.

An exemplary photolithography process for various patterning purposes may include processing steps of photoresist coating, soft baking, mask aligning, exposing, post-exposure baking, developing photoresist and hard baking. The photolithography exposing process may also be implemented or replaced by other proper methods such as maskless photolithography, electron-beam writing, ion-beam writing, and molecular imprint.

In another embodiment, the hard mask layer used to form the gate stacks includes silicon nitride. The silicon nitride layer is further patterned using a photolithography process to form a patterned photoresist layer and an etching process to etch the silicon nitride within the openings of the patterned photoresist layer. Alternatively, other dielectric material may be used as the patterned hard mask. For example, silicon oxynitride may be used as the hard mask. In another embodiment, the silicon oxide layer used for the interfacial layer between the high k dielectric layer and the substrate can be formed by thermal oxidation or atomic layer deposition (ALD).

The present disclosure is not limited to applications in which the semiconductor structure includes a MOS transistor, and may be extended to other integrated circuit having a metal gate stack. For example, the semiconductor structure 200 may include a dynamic random access memory (DRAM) cell, a single electron transistor (SET), and/or other microelectronic devices (collectively referred to herein as microelectronic devices). In another embodiment, the semiconductor device 150 includes FinFET transistors. Of course, aspects of the present disclosure are also applicable and/or readily adaptable to other type of transistor, including single-gate transistors, double-gate transistors and other multiple-gate transistors, and may be employed in many different applications, including sensor cells, memory cells, logic cells, and others.

Although embodiments of the present disclosure have been described in detail, those skilled in the art should understand that they may make various changes, substitutions and alterations herein without departing from the spirit and scope of the present disclosure. For example, the semiconductor substrate may include an epitaxial layer. For example, the substrate may have an epitaxial layer overlying a bulk semiconductor. Further, the substrate may be strained for performance enhancement. For example, the epitaxial layer may include a semiconductor material different from those of the bulk semiconductor such as a layer of silicon germanium overlying a bulk silicon, or a layer of silicon overlying a bulk silicon germanium formed by a process including SEG. Furthermore, the substrate may include a semiconductor-on-insulator (SOI) structure such as a buried dielectric layer. Alternatively, the substrate may include a buried dielectric layer such as a buried oxide (BOX) layer, such as that formed by a method referred to as separation by implantation of oxygen (SIMOX) technology, wafer bonding, selective epitaxial growth (SEG), or other proper method.

The disclosed method and device structure can eliminate or reduce gap-filling issue at small pitch and/or contact open issue. In other embodiments, the method and device structure to overcome the above issues include optimizing spacer and ESL profile, using a good gap-filling dielectric material, removing the hard mask and polysilicon before the ILD deposition, or combinations thereof.

Thus, the present disclosure provides an integrated circuit having metal gate stacks. The integrated circuit includes a semiconductor substrate; a gate stack disposed on the semiconductor substrate, wherein the gate stack includes a high k dielectric layer and a first metal layer disposed on the high k dielectric layer; and a raised source/drain region configured on a side of the gate stack.

In the disclosed integrated circuit, the gate stack may further include a gate spacer interposed between the gate stack and the raised source/drain region. The raised source/drain region may include silicon. The semiconductor substrate may include a silicon germanium (SiGe) feature underlying the raised source/drain region. The source/drain region and the gate stack may be portions of a P metal-oxide-semiconductor (PMOS) transistor. The raised source/drain region is formed by an epitaxy process in embodiment. The gate stack may further include an interfacial layer interposed between the semiconductor substrate and the high k dielectric material layer. The interfacial layer may include silicon oxide. The first metal layer may include a metal material selected from the group consisting of Ti, TiN, TaN, TiAl, TiAlN, WN and a combinations thereof. The gate stack may further include a second metal layer disposed on the first metal layer. The second metal layer may include a metal material selected from the group consisting of tungsten (W) and aluminum (Al). The gate stack may further include an additional material interposed between the first metal layer and the high k dielectric material, having at least one of LaO and Al2O3. The raised source/drain region may have a thickness of about 200 angstrom.

The present disclosure also provides another embodiment of an integrated circuit having metal gate stacks. The integrated circuit includes a semiconductor substrate; an N metal-oxide-semiconductor (NMOS) transistor formed on the semiconductor substrate, wherein the NMOS transistor includes a first gate stack having a high k dielectric layer and a first metal layer on the high k dielectric layer; a first gate spacer disposed on sidewalls of the first gate stack; and a first raised source and a first raised drain laterally contacting sidewalls of the first gate spacer. The integrated circuit also includes a PMOS transistor formed on the semiconductor substrate, wherein the PMOS transistor includes a second gate stack having the high k dielectric layer and a second metal layer on the high k dielectric layer; a second gate spacer disposed on sidewalls of the second gate stack; and a second raised source and a second raised drain laterally contacting sidewalls of the second gate spacer.

The disclosed integrated circuit may further include a first source and a first drain including silicon and underlying the first raised source and first raised drain, respectively; and a second source and a second drain including silicon germanium (SiGE) and underlying the second raised source and second raised drain, respectively. The first raised source, the first raised drain, the second raised source and the second raised drain may include silicon.

The present disclosure also provides one embodiment of a method for making a semiconductor device. The method includes forming, on a semiconductor substrate, a first gate stack in an N metal-oxide-semiconductor (NMOS) transistor region and a second gate stack in a PMOS transistor region; forming epitaxy silicon germanium (SiGe) source and drain in the semiconductor substrate within the PMOS transistor region; forming gate spacers on sidewalls of the first gate stack and sidewalls of the second gate stack; and applying an epitaxy process to form raised sources and drains within the NMOS transistor region and the PMOS transistor region, after the forming of the gate spacers. The disclosed method may further include forming silicide on the raised sources and drains. The applying of the epitaxy process may include applying a silicon epitaxy process.

The present disclosure also provides another embodiment of a method for making a semiconductor device having metal gate stacks. The method includes forming a dummy gate stack on a semiconductor substrate; forming epitaxy silicon germanium (SiGe) source and drain in the semiconductor substrate, aligned with the gate stack; forming a gate spacer on sidewalls of the gate stack; and applying an epitaxy process to form a raised source and a raised drain, aligned with the gate spacer and laterally contacting sidewalls of the gate spacer.

The method may further include forming salicide on the raised source and drain. In another embodiment, the method further includes forming an inter-level dielectric (ILD) on the semiconductor substrate; removing at least a portion of the dummy gate stack, resulting a gate trench; and forming a metal layer in the gate trench. The removing of at least portion of the dummy gate stack may include removing polysilicon from the dummy gate stack.

The present disclosure also provides another embodiment of a method for making a semiconductor device having metal gate stacks. The method includes forming a gate stack on a semiconductor substrate; forming a gate spacer on sidewalls of the gate stack; applying an epitaxy process to form a raised source and a raised drain, aligned with the gate spacer and laterally contacting sidewalls of the gate spacer; forming an inter-level dielectric (ILD) on the semiconductor substrate; removing a portion of the gate stack, resulting a gate trench; and forming a metal layer in the gate trench. In this method, the forming of the gate stack may include forming a high k dielectric layer and a polysilicon layer. The removing of the portion of the gate stack may include removing the polysilicon layer. The method may further include forming an epitaxy silicon germanium (SiGe) feature in the semiconductor substrate, aligned with the gate stack and before the applying of the epitaxy process.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An integrated circuit having metal gate stacks, comprising:
a semiconductor substrate;
a gate stack disposed on the semiconductor substrate, wherein the gate stack includes a high k dielectric layer and a first metal layer disposed on the high k dielectric layer; and
a raised source/drain region configured on a side of the gate stack and formed by an epitaxy process,
wherein the semiconductor substrate includes a silicon germanium (SiGe) feature underlying the raised source/drain region.

2. The integrated circuit of claim 1, wherein the gate stack further comprises a gate spacer interposed between the gate stack and the raised source/drain region.

3. The integrated circuit of claim 1, wherein the raised source/drain region comprises silicon.

4. The integrated circuit of claim 1, wherein the source/drain region and the gate stack are portions of a P metal-oxide-semiconductor (PMOS) transistor.

5. The integrated circuit of claim 1, wherein the gate stack further comprises a silicon oxide layer interposed between the semiconductor substrate and the high k dielectric material layer.

6. The integrated circuit of claim 1, wherein the first metal layer comprises a metal material selected from the group consisting of Ti, TiN, TaN, TiAl, TiAlN, WN and a combinations thereof.

7. The integrated circuit of claim 1, wherein the gate stack further comprises a second metal layer disposed on the first metal layer.

8. The integrated circuit of claim 7, wherein the second metal layer comprises a metal material selected from the group consisting of tungsten (W) and aluminum (Al).

9. The integrated circuit of claim 1, wherein the gate stack further comprises an additional material interposed between the first metal layer and the high k dielectric material, having at least one of LaO and Al2O3.

10. The integrated circuit of claim 1, wherein the raised source/drain region comprises a thickness of about 200 angstrom.

11. An integrated circuit having metal gate stacks, comprising:
a semiconductor substrate;
an N metal-oxide-semiconductor (NMOS) transistor formed on the semiconductor substrate, wherein the NMOS transistor includes
a first gate stack having a high k dielectric layer and a first metal layer on the high k dielectric layer;
a first gate spacer disposed on sidewalls of the first gate stack; and
a first raised source and a first raised drain laterally contacting sidewalls of the first gate spacer; and
a PMOS transistor formed on the semiconductor substrate, wherein the PMOS transistor includes
a second gate stack having the high k dielectric layer and a second metal layer on the high k dielectric layer;
a second gate spacer disposed on sidewalls of the second gate stack; and
a second raised source and a second raised drain laterally contacting sidewalls of the second gate spacer.

12. The integrated circuit of claim 11, further comprising:
a first source and a first drain including silicon and underlying the first raised source and first raised drain, respectively; and
a second source and a second drain including silicon germanium (SiGE) and underlying the second raised source and second raised drain, respectively.

13. The integrated circuit of claim 11, wherein the first raised source, the first raised drain, the second raised source and the second raised drain each comprises silicon.

14. A method for making a semiconductor device having metal gate stacks comprising:
forming a dummy gate stack on a semiconductor substrate;
forming epitaxy silicon germanium (SiGe) source and drain in the semiconductor substrate, aligned with the gate stack;
forming a gate spacer on sidewalls of the gate stack; and
thereafter, applying an epitaxy process to form a raised source and a raised drain, aligned with the gate spacer and laterally contacting sidewalls of the gate spacer.

15. The method of claim 14, further comprising forming salicide on the raised source and drain.

16. The method of claim 14, further comprising;
forming an inter-level dielectric (ILD) on the semiconductor substrate;
removing at least a portion of the dummy gate stack, resulting a gate trench; and
forming a metal layer in the gate trench.

17. The method of claim 16, wherein the removing of at least portion of the dummy gate stack comprises removing polysilicon from the dummy gate stack.

18. The method of claim 14, further comprising forming an epitaxy silicon germanium (SiGe) feature in the semiconductor substrate, aligned with the gate stack and before the applying of the epitaxy process.

19. The method of claim 14,
wherein the forming of a dummy gate stack includes forming a first gate stack in a P-type metal-oxide-semiconductor (PMOS) transistor region;
further including forming a second gate stack in an N-type metal-oxide-semiconductor (NMOS) transistor region; and
wherein the forming of epitaxy silicon germanium (SiGe) source and drain includes forming the epitaxy silicon germanium (SiGe) source and drain within the PMOS transistor region.

20. The method of claim 14, wherein the applying of the epitaxy process comprises applying a silicon epitaxy process.
